(19) United States
(12) Patent Application Publication
(10) Pub. No.: US 2007/0026690 A1
(43) Pub. Date: Feb. 1, 2007

(54) Selective frequency UV heating of films

(76) Inventor: Woo Sik Yoo, Palo Alto, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/505,662

(22) Filed: Aug. 16, 2006

Related U.S. Application Data
(63) Continuation-in-part of application No. 10/982,045, filed on Nov. 5, 2004.

(51) Int. Cl. H01L 21/31

(52) U.S. Cl. 438/787; 257/E21.284

(57) ABSTRACT

A layer, such as a dielectric, formed on a substrate, such as a silicon substrate, is heated by selecting a specific wavelength or energy for the material of the layer, such that photons readily pass and are absorbed by the material and then reflected from the interface of the layer and the substrate.

### CROSS REFERENCE TO RELATED APPLICATIONS

This application is a continuation-in-part of U.S. Patent application Ser. No. 10/982,045, filed Nov. 5, 2004, which is incorporated by reference in its entirety.

### BACKGROUND

1. Field of Invention

This invention generally relates to semiconductor manufacturing methods and, more particularly, to a method for heating films during processing.

2. Related Art

Typical semiconductor devices are manufactured by first providing a bulk material, such as Si, Ge, and GaAs in the form of a semiconductor substrate or wafer. Dopants are then introduced into the substrate to create p- and n- type regions in a process or reaction chamber. The dopants can be introduced using thermal diffusion or ion implantation methods. In the latter method, the implanted ions will first be distributed interstitially. Thus, to render the doped regions electrically active as donors or acceptors, the ions must be introduced into substitutional lattice sites. This “activation” process is accomplished by heating the bulk wafer, generally in the range of between 600° C. to 1300° C. When using a silicon wafer, for example, a dielectric layer, such as silicon oxide can be “grown” or deposited to provide an electrical interface. Finally a metallization, such as aluminum, is applied using, for example, either an evaporation or a sputtering technique.

The quality of thin oxides or dielectrics, such as for gate insulating, is becoming more important in the field of semiconductor devices fabrication. Many broad categories of commercial devices, such as electrically erasable programmable read only memories (EEPROMs), dynamic random access memories (DRAMs), and more recently, even high-speed basic logic functions, depend on the ability to reproduce high quality, very thin oxide layers. High quality dielectrics are needed in such devices to achieve satisfactory devices performance both in terms of speed and longevity.

Present gate insulating layers fall short of the requirements necessary for future devices. Most conventional gate insulating layers are pure silicon oxide SiO₂ films formed by thermal oxidation. Others employ a combination of a high temperature deposited SiO₂ layer on a thermally grown layer.

As semiconductor devices and geometries become smaller and smaller, gate oxides need to be thinner and thinner, e.g., on the order of 15 to 20 Å. However, as the oxide layer becomes thinner, tunneling leakage can become a problem, especially with low quality oxides. With current techniques for oxide growth, the quality of the oxide layer is not sufficient to sustain very thin oxide layers. In general, one way to improve oxide layer quality is to increase the temperature or thermal energy at which the oxide is grown. One problem is that as temperature increases, other dopants may diffuse, which may adversely affect other characteristics of the semiconductor device. On the other hand, when thermal energy, which already has relatively low electron energy, is reduced, the thermally grown oxide exhibits poor qualities, due in part to factors such as poor integration and diffusion effects. Thus, it is difficult to form thin oxide layers with consistent quality and thickness using conventional thermal processes.

Pure SiO₂ layers are unsuitable for devices requiring thin or very thin dielectric or oxide films because their integrity is inadequate when formed and they suffer from their inherent physical and electrical limitations. SiO₂ layers also suffer from their inability to be manufactured uniformly and defect-free when formed as these thin layers. Additionally, subsequent VLSI processing steps may continue to degrade the already fragile integrity of thin SiO₂ layers. Furthermore, pure SiO₂ layers tend to degrade when exposed to charge injection, by interface generation and charge trapping. As such, pure SiO₂ layers are inadequate as thin films for future scaled technologies.

In tunnel oxides, breakdowns occur because of the trapping of charge in the oxides, thereby gradually raising the electric field across the oxides until the oxides can no longer withstand the induced voltage. Higher quality oxides trap fewer charges over time and will therefore take longer to break down. Thus, higher quality thin film oxides are desired.

Furthermore, usually oxide films are amorphous, i.e., there is a shortened periodicity, such that oxide atoms in close proximity are similar, but as atoms move farther away, their structure becomes unpredictable. The oxide layer may further have unpaired or dangling bonds. If there is an ion or charge, then dangling bonds may be problematic, resulting, for example, large performance variations between devices.

Thus, it is desirable to make the dangling bonds inactive. One method is to expose the film with the dangling bonds to hydrogen, where the reaction will make the dangling bonds electrically inactive. However, the reaction requires high energy, which can be provided by increasing the temperature or thermal energy. At high temperatures, oxide will grow and would thus undesirably increase the thickness of the “thin” oxide layer.

Therefore, there is a need for methods of forming thin film oxides or dielectrics that overcome the disadvantages of conventional techniques discussed above.

### SUMMARY

According to one aspect of the present invention, light energy, such as ultraviolet (UV) light, is used to irradiate a dielectric or oxide film during and/or between formation of such a film. The additional energy supplied from the light source allows a lower process temperature to form a high quality thin film.

In one embodiment, light having a wavelength between 150 nm and 1 μm is used to irradiate a semiconductor wafer within a process chamber for a time between 0.1 ms and 3600 s, at a temperature between 0° C. and 1300° C. and a pressure between 0.001 mTorr and 1000 Torr to form a thin dielectric film having a thickness between 1 Å and 1000 Å. The irradiation is performed simultaneously with a conventional thin film formation process or can be performed after formation of the film, either in situ or in another chamber. Process gases used with the irradiation may be any gas or gases used in film formation, such as, but not limited to air, O₂, N₂, HCl, NH₃, N₂H₄, and H₂O.

In one embodiment, the process chamber includes a light source, such as a grid lamp or bank of lamps overlying the wafer. The light source is located between a reflector at the top portion of the chamber and the wafer. Light sources may include a halogen lamp, a mercury lamp, or a cadmium lamp that are arranged as a continuous lamp or a series of lamps. In one embodiment, a window is located between the wafer and the light source, where the window can be a filter or a non-filter. A controllable heating source, such as a hot plate, lamps, or a susceptor, heats the wafer while process gases are introduced into the chamber. A transport mechanism has the ability to move the wafer into and out of the chamber, as well as within the chamber. The pressure within the process chamber is also adjustable from at least 0.001 mTorr to 1000 Torr. At least one gas inlet/outlet port allows process and other gases to be introduced into and expelled from the chamber. The process chamber can be a single wafer processing chamber or a wafer batch processing chamber.

By using UV light in conjunction with thermal energy, the resulting oxide or dielectric layer can be made as a thin film (e.g., approximately 100 nm or less), while maintaining a high quality level. Lower temperatures may be used, which increases the oxide quality, such as decreasing adverse diffusion effects, charge trapping, and dangling bonds. Electrical properties of the film are also improved. The number of unpaired bonds, such as in a silicon-silicon dioxide interface, are greatly reduced. Other advantages of the present invention include reduction of unwanted electric trap/midgap density of states, reduction of unwanted Si—OH bonds, and reduction of H₂O in the film.

According to another aspect of the present invention, specific frequencies or wavelengths of ultraviolet light are used to heat an interface between a film, such as a dielectric, and a substrate, such as silicon. The frequency is selected based on the type of material used for the film, such that the photons or light energy is absorbed by the material, i.e., the material is transparent to the light energy. This enables light energy to pass through the film to the interface between the film and substrate. As a result, the material is heated outward from the interface, enabling the material to be quickly heated. This provides a large temperature gradient from the film surface to the interface of the film and silicon substrate.

These and other features and advantages of the present invention will be more readily apparent from the detailed description of the preferred embodiments set forth below taken in conjunction with the accompanying drawings.

### BRIEF DESCRIPTION OF THE DRAWINGS

FIG. 1 is a flow chart of one embodiment of the present invention for forming a dielectric layer on a wafer;

FIG. 2 is a schematic illustration of a side view of an embodiment of a semiconductor wafer processing system for performing the process of FIG. 1 ;

FIG. 3 is a chart showing the absorption coefficient as a function of wavelength for various semiconductor materials;

FIG. 4 is a chart showing transmittance as a function of wavelength for fused quartz; and

FIG. 5 is a simplified cross-sectional view of a portion of a wafer treated with ultraviolet light according to one embodiment.

Embodiments of the present invention and their advantages are best understood by referring to the detailed description that follows. It should be appreciated that like reference numerals are used to identify like elements illustrated in one or more of the figures.

### DETAILED DESCRIPTION

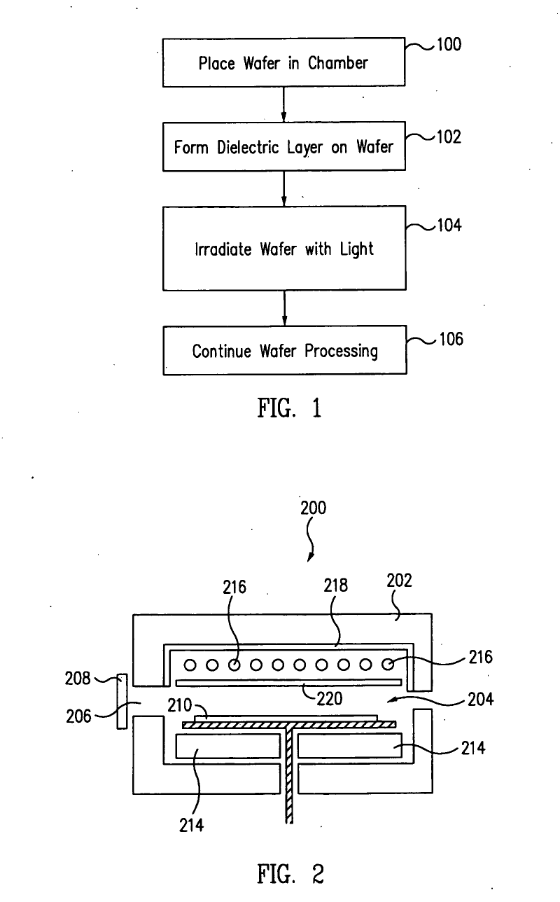

FIG. 1 is a flow chart showing one embodiment of the present invention for forming dielectric films. In step 100, a semiconductor wafer is placed into a process chamber. The wafer can be at different stages of processing, depending on the type of film to be formed on the wafer. In step 102, a dielectric or oxide layer, such as a gate insulating film, is formed on the wafer, such as by introducing one or more process gases into the process chamber. The process gases are used for formation of a dielectric or oxide layer on the wafer. The formation process can be growth or deposition of the oxide layer by chemical vapor deposition (CVD) or physical vapor deposition (PVD) or spin coating using a liquid source. Suitable process gases include, but are not limited to, air, 02, N₂, HC1, NH₃, and H₂O. Pressure and temperature within the chamber are adjusted depending on the process and system parameters. For example, the pressure may range from 0.001 mTorr to 1000 Torr, and temperature may range from 0° C. to 1300° C. In one embodiment, the temperature is less than 800° C. Because the processes of growing or depositing an oxide layer are well known, specific process parameters will not be given. It should be noted that those skilled in the art will use appropriate process parameters depending on the characteristics needed for the film. One important feature of the present invention is that the temperature does not need to be increased significantly during formation of a thin dielectric film to increase the quality of the film.

In step 104, the wafer is irradiated with light or photon energy. In one embodiment, the irradiation is performed during formation of the dielectric layer. In another embodiment, the irradiation is performed after formation of the dielectric layer or film, such as between film formation cycles for curing. Thus, the light source can be turned off and on during different periods of the film formation and for different durations. For example, the light source can be turned on continuously from the beginning of the film formation process to the end of the process or during any one or more periods in between.

Further, in one embodiment, the irradiation in step 104 can be performed in situ. In other embodiments, the irradiation is performed in a separate process chamber, such as processes in which the wafer is moved from the deposition process chamber to another chamber, either associated with the same machine or in a separate machine. In one embodiment, the light has a wavelength between 150 nm and 1 μm in the visible and ultraviolet (UV) range. UV light, especially, has relatively high energy, i.e., corresponding to 3 eV and higher. After the dielectric layer is formed in steps 102 and 104, processing continues in step 106, as needed for manufacturing the semiconductor device.

FIG. 2 shows a simplified cross-sectional view of a portion of a process reactor 200 in accordance with one embodiment of the present invention. Process reactor 200 includes a shell 202, which can be made of aluminum or other suitable metal, that substantially encloses a process chamber 204, such as a load lock chamber. Process chamber 204 may be formed from a process tube, such as made from quartz, silicon carbide, A1₂0₃, or other suitable material. To conduct a process, process chamber 204 should be capable of being pressurized. Typically, chamber 204 should be able to withstand internal pressures of about 0.001 mTorr to 1000 Torr, preferably between about 0.1 Torr and about 760 Torr. An opening 206 to process chamber 204 is sealable by a gate valve 208. Gate valve 208 is operable to seal opening 206, such as during wafer processing, and to uncover opening 206, such as during wafer transfer into and out of chamber 204. Robot assemblies or other mechanisms (not shown) can be used to transfer a wafer 210, such as from a wafer cassette, to and from the process chamber.

Located within process chamber 204 is a wafer support 212 that supports wafer 210 during processing. Wafer support 212 can be fixed or movable to position the wafer up and down or rotate the wafer within the process chamber. Wafer support 212 can be a plate (as shown), individual standoffs, or any other suitable support. A heat source 214 is also contained within process chamber, such as below wafer 210. Heat source can be any suitable wafer heating source, such as a susceptor, hot plate, or lamps. Lamps may be a single lamp or an array of individual lamps, positioned at distances both from the wafer and from each other to uniformly heat the overlying wafer.

A light source 216 is located above wafer 210 for providing light energy, such as UV energy, to the wafer during processing, as described above. Light source 216 can be one continuous lamp or a bank of lamps. Suitable lamp types include halogen lamps, mercury lamps, xenon lamps, argon lamps, krypton lamps, and cadmium lamps. The choice of light source depends on various factors, including desired light energy. For example, tungsten halogen lamps can be used to provide visible and infrared light. Mercury (Hg) lamps, at low, medium, or high pressure, gives spectral lines, but with different intensity ratio. Lamp activation and operation can be by any suitable conventional method.

The wavelength or frequency of the light can be adjusted, based on various factors, such as the process and type of layer formed. In one embodiment, the wavelength of the light is between 150 nm and 1 μm. In order to maximize the amount of light energy incident on wafer 210, a reflector 218 may be located above light source 215 to reflect light back onto wafer 210. Reflector 218 may also be located along the outer periphery of the light source. In different embodiments, reflector 218 may be a separate reflector, such as a mirror, a coating on the inner surface of process chamber 204, or a combination of both. Optionally, a window 220 is located between light source 216 and wafer 210 to allow light to pass, either filtered or unfiltered, to wafer 210 during processing. Accordingly, window 220 can be a filtering window or a non-filtering window, made of materials such as quartz and ZnSe.

Various process chambers and processes can be used with the present invention. For example, the process chamber can be a single wafer chamber for rapid thermal processing or multiple wafer systems. Processing can be thermal annealing, dopant diffusion, thermal oxidation, nitridation, chemical vapor deposition, and similar processes, in which a processing step forms a thin dielectric layer where light energy used during layer formation improves the quality of the resulting layer.

One advantage of using light energy is the high energy levels as compared to thermal energy from conventional heat sources, such as hot plates and susceptors. Because thermal energy has low efficiency, when it is converted to electron energy, the energy level is low. However, light energy, within the visible light spectrum, corresponds to more than 1 eV, while light in the ultraviolet spectrum corresponds to 3 eV or higher. Thus, high energy in the form of light can be supplied to the wafer during processing, in addition to thermal energy. The light does not grow the dielectric or oxide layer, but rather improves the quality of such a layer. Additional advantages include reduction of charge trapping, reduction or elimination of dangling bonds, and improvement of electrical properties of the resulting device.

According to another embodiment of the present invention, ultraviolet energy 216 or energy from lamp 508 is directed toward the surface of a dielectric film formed over a silicon substrate or layer. The wavelength or energy of the light is selected based on the material of the dielectric film. In particular, the wavelength is selected such that the material is transparent to the light. In this case, the light passes through the material and is reflected at the interface of the material and the silicon substrate. As a result, the dielectric is heated, as the light is absorbed by the material and reflected from the interface.

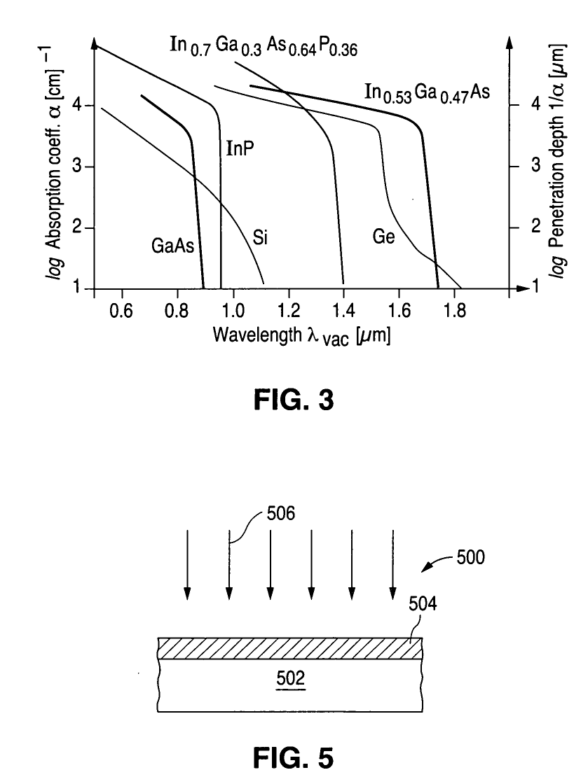

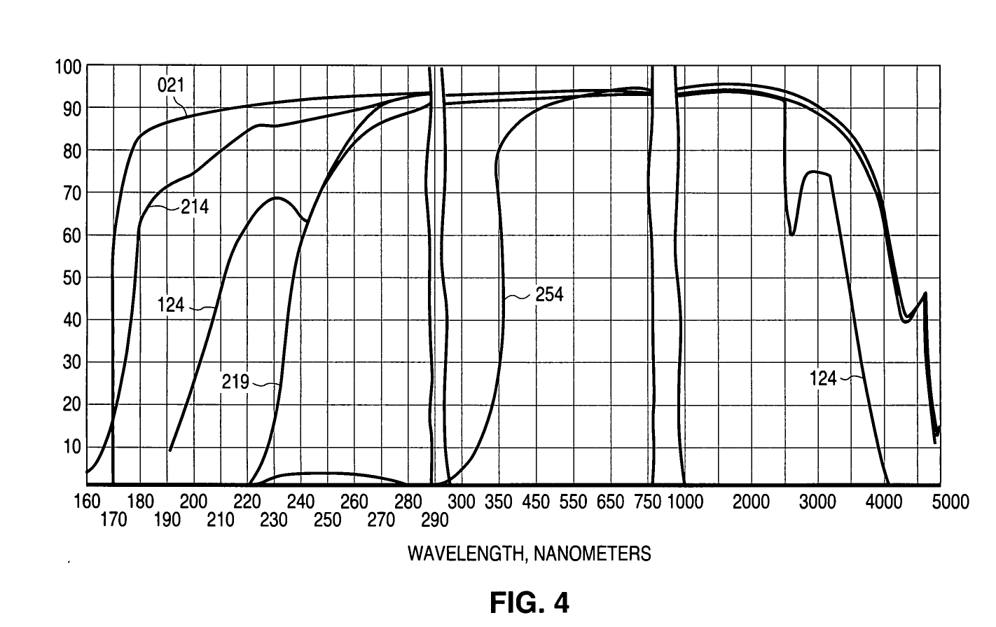

FIGS. 3 and 4 are charts showing absorption/transmittance for various materials as a function of wavelength. FIG. 3 shows the absorption coefficient for various semiconductor devices, and FIG. 4 shows the transmittance percentage for fused quartz. Absorption charts or tables are well known. Consequently, with any desired material, a wavelength or range of wavelengths can be selected which readily passes through the desired material. With higher wavelengths, the energy would be mainly reflected by the material. Thus, by selecting light at a certain wavelength or range of wavelengths, specific layers on a substrate can be quickly and efficiently heated, thereby improving the semiconductor manufacturing process. Equivalently, a frequency or frequency range (speed of light/wavelength) or an energy or energy range in eV (1240/wavelength (nm)) can be selected so that the material is transparent to the corresponding light or energy.

Any suitable light or energy source, such as an ultraviolet or filament lamp, that selectively generates light at desired wavelengths or energies may be suitable for use with the present invention. For example, the desired frequency or energy of the light can be produced by a plasma enclosed in a chamber, where the plasma within the chamber can be generated with microwave, RF, inductively coupled, capacitively coupled, or by electrodes. Those skilled in the art will appreciate other types of light sources, as well as ways to select the desired frequencies or energies. Accordingly, no additional detail is provided.

FIG. 5 is an exemplary simplified cross-sectional view of a semiconductor device 500 treated by ultraviolet light at a specifically selected frequency based on the material of the layer being treated. Device 500 includes a silicon substrate 502 having a dielectric layer or film 504 formed on at least a portion of the surface of silicon substrate 502. Silicon substrate 502 can be any type of silicon substrate including substrates containing oxygen. Substrate 502 may already have been subjected to a variety of processes associated with the formation of integrated circuits. Silicon substrate can also have other types of layers or materials deposited on portions of the substrate not covered by dielectric layer 504. Dielectric layer 504 can be any suitable insulating film or layer used during the device manufacturing process. The thickness of the dielectric layer depends on the type of type and/or function of the layer.

Light 506 at the selected wavelength or energy is directed at dielectric layer 504. The photons readily pass through the material to the interface of dielectric layer 504 and substrate 502, where energy not already absorbed by the material is reflected back through it. This quickly and effectively heats the dielectric material. Typical treatment times depend on the material characteristics and process goals of the treatment and can be as short as 1 μsec or less or as long as 12 hours or more. Optimal treatment times can be calculated or based on experimental results for example. In some embodiments, the selected wavelength treatment of the film is provided in conjunction with heat. As a result, with or without the added heat, a large temperature gradient is generated in the depth direction from the dielectric surface to the interface between silicon and dielectric material.

The above-described embodiments of the present invention are merely meant to be illustrative and not limiting. For example, dielectric or oxide films are discussed here; however, other layers formed during semiconductor processing may also benefit from irradiation with a light source according to the present invention. The light energy may be other than ultraviolet, and the substrate may be other than silicon. Furthermore, the light source can be used to heat from the backside or the front side of the wafer. It will thus be obvious to those skilled in the art that various changes and modifications may be made without departing from this invention in its broader aspects. Therefore, the appended claims encompass all such changes and modifications as fall within the true spirit and scope of this invention.

What is claimed is:

1. A method for processing semiconductor wafers in a processing chamber having a light source, the method comprising:
providing a semiconductor substrate with a layer formed thereon, wherein the layer comprises a first material;
selecting a first frequency for the light source based on absorption characteristics of the first material; and
irradiating the layer with light at the first frequency to heat the layer.

2. The method of claim 1, wherein the layer is a dielectric layer.

3. The method of claim 1, wherein the first frequency is in the ultraviolet range.

4. The method of claim 1, wherein the irradiation is by a light source located above the substrate.

5. The method of claim 1, further comprising thermally heating the substrate and layer during the irradiation.

6. The method of claim 1, wherein the frequency selection is based on frequencies that are readily absorbed by the first material.

7. The method of claim 1, further comprising reflecting the light from an interface of the substrate and the layer.

8. The method of claim 1, wherein the substrate comprises silicon.

9. The method of claim 1, wherein the light source is lamp-based.

10. The method of claim 1, wherein the light source is plasma-based.

11. A method for manufacturing a semiconductor device in a process chamber, the method comprising:
providing a semiconductor substrate in the chamber;
forming a film over the substrate; and
irradiating the film with light to heat the film, wherein the light having a selected energy dependent on the material of the film.

12. The method of claim 11, wherein the semiconductor substrate comprises silicon.

13. The method of claim 11, wherein the film is a dielectric film.

14. The method of claim 11, wherein the material of the film is transparent to the light having the selected energy.

15. The method of claim 14, further comprising reflecting the light off an interface of the substrate and the film.

16. The method of claim 13, wherein the irradiation is by a light source located above the substrate.

17. The method of claim 11, further comprising thermally heating the substrate and film during the irradiation.

18. A wafer processing system comprising:
a process chamber;
a gas distribution system configured to introduce a process gas into the chamber;
a wafer support for supporting a wafer during processing;
a heating element positioned below the wafer; and
an irradiating light source positioned above the wafer, wherein the light source is configured to emit light at a selected frequency or energy that is dependent on the material of a layer on the wafer to heat the layer.

19. The processing system of claim 18, wherein the light source is selected from the group consisting of halogen, mercury, xenon, argon, krypton, and cadmium lamps and plasma-based light sources.

20. The processing system of claim 18, wherein the heating element is a thermal heating element.

21. The processing system of claim 18, wherein the frequency or energy is selected based on the absorption of the material to the light.

22. The processing system of claim 18, wherein the material is transparent to the selected frequency or energy of the light.
